(19) United States
(12) Patent Application Publication
(10) Pub. No.: US 2012/0195127 A1
(43) Pub. Date: Aug. 2, 2012

(54) NON-VOLATILE SEMICONDUCTOR MEMORY

(76) Inventor: Yoshihiro NAKATAKE, Miyazaki (JP)

(21) Appl. No.: 13/356,998

(22) Filed: Jan. 24, 2012

(30) Foreign Application Priority Data
Feb. 2, 2011 (JP) 2011-020988

(51) Int. Cl. G11C 16/10

(52) U.S. Cl. 365/185.23

(57) ABSTRACT

A non-volatile semiconductor memory includes a plurality of memory cells and a driver for selectively driving the memory cells. The driver includes a first drive portion and a second drive portion. The first drive portion is provided for applying a source voltage higher than a power source voltage to a source region of the memory cell. The second drive portion is provided for applying a specific low voltage to a drain region of the memory cell for writing data having a first logic level, so that a writing current flows in the memory cell. Further, the second drive portion is provided for applying a specific high voltage higher than the power source voltage as a writing prohibition voltage to a drain region of the memory cell for writing data having a second logic level, so that the writing current is prevented from flowing in the memory cell.

### BACKGROUND OF THE INVENTION AND RELATED ART STATEMENT

The present invention relates to a non-volatile semiconductor memory.

Patent Reference has disclosed a flash memory of a split gate type as a conventional non-volatile semiconductor memory. The flash memory disclosed in Patent Reference includes a memory cell array, a word line driver, a source line driver, and a column decoder.

Patent Reference: Japanese Patent Publication No. 2004-213879

In the flash memory disclosed in Patent Reference, a plurality of source lines and a plurality of word lines are formed in the memory cell array, and the source lines and the word lines are arranged to cross each of a plurality of bit lines. Further, the memory cell array includes a memory cell of the split gate type disposed on each of crossing points of the bit line and the source lines (or the word lines).

In the flash memory disclosed in Patent Reference, the memory cell of the split gate type is formed of a transistor having a MOS (Metal Oxide Semiconductor) structure, in which a gate region thereof is divided into a floating gate for controlling an accumulated electric charge amount and a selection gate for selecting a cell as an access target. A source region of the memory cell is connected to the source line, and a drain region of the memory cell is connected to the bit line. Further, the selection gate is connected to the word line.

In the flash memory disclosed in Patent Reference, the word line driver is provided for applying various drive voltages corresponding to each of a memory writing operation, a memory reading operation, and a memory deleting operation to the word lines. The source line driver is provided for applying various drive voltages corresponding to each of the memory writing operation, the memory reading operation, and the memory deleting operation to the source lines. The column decoder is provided for applying various drive voltages corresponding to each of the memory writing operation, the memory reading operation, and the memory deleting operation to the bit lines.

In the flash memory disclosed in Patent Reference, when each of the memory cells is in an initial state, electrons are not charged to the floating gate. When the memory cell is read out in the initial state, a voltage corresponding to data “1” is transmitted on the bit line. In other words, the state in which electrons are not charged to the floating gate corresponds to the writing state of the data “1” in the memory cell.

In the flash memory disclosed in Patent Reference, when data “0” is written in the memory cell connected to specific one of the word lines, first, the word driver applies a specific selection voltage to the specific one of the word lines. At the same time, the source line driver applies a specific high voltage to the source line, and the column decoder applies a specific low voltage to the bit line. Accordingly, the selection gate and the floating gate of the memory cell are turned on, so that a writing current flows into the memory cell. As a result, electrons are charged to the floating gate due to the writing current.

On the other hand, when the data “1” is written in the memory cell connected to specific one of the word lines, the column decoder applies a high voltage corresponding to a power source voltage to the bit line. Accordingly, the high voltage is applied to the source line and the bit line of the memory cell, so that the selection gate and the floating gate of the memory cell are turned off, and the writing current does not flow into the memory cell. As a result, the memory cell becomes the wiring state of the data “1”.

In the flash memory disclosed in Patent Reference, when the data “0” is written in the large number of the memory cells, the wiring current flowing into each of the memory cells has a large total sum, thereby decreasing the power source voltage. As described above, the high voltage corresponding to the power source voltage is applied to the bit line of the memory cell, to which the data “0” is written. Accordingly, it is possible to prevent the wiring current from flowing into the memory cell, that is, to maintain the selection gate in the off state. However, the selection gate may be turned on due to the decrease in the power source voltage, so that the wiring current may flow into the memory cell. If the wiring current flows into the memory cell, the data “0” is erroneously written to the memory cell.

In view of the problems described above, an object of the present invention is to provide a non-volatile semiconductor memory capable of solving the problems of the conventional non-volatile semiconductor memory. In the present invention, it is possible to prevent data from being erroneously written to the non-volatile semiconductor memory of the present invention.

Further objects and advantages of the invention will be apparent from the following description of the invention.

### SUMMARY OF THE INVENTION

In order to attain the objects described above, according to an aspect of the present invention, a non-volatile semiconductor memory includes a plurality of memory cells each having an MOSFET structure and a driver for selectively driving the memory cells.

According to the aspect of the present invention, the driver includes a first drive portion and a second drive portion. The first drive portion is provided for applying a source voltage higher than a power source voltage to a source region of each of writing subject memory cells among the memory cells based on the power source voltage according to a wiring instruction for wiring data to the writing subject memory cells. The second drive portion is provided for applying a specific low voltage to a drain region of specific ones of the writing subject memory cells, to which first data having a first logic level is to be written, according to the wiring instruction, so that a writing current flows in the specific ones of the writing subject memory cells. Further, the second drive portion is provided for applying a specific high voltage higher than the power source voltage as a writing prohibition voltage to a drain region of specific ones of the writing subject memory cells, to which second data having a second logic level different from the first logic level is to be written, according to the wiring instruction, so that the writing current is prevented from flowing in the specific ones of the writing subject memory cells.

In the aspect of the present invention, it is configured such that the writing current flows between the source region and the drain region of each of the specific ones of the writing subject memory cells having the first logic level among the memory cells. As a result, the specific ones of the writing subject memory cells are set in a data written state with the first logic level. Further, it is configured such that the high source voltage is applied to the source region and the writing prohibition voltage higher than the power source voltage is applied to the drain region of each of the specific ones of the writing subject memory cells having the second logic level among the memory cells. As a result, the writing current is prevented from flowing in the specific ones of the writing subject memory cells, and the specific ones of the writing subject memory cells are set in the data written state with the second logic level.

Accordingly, in the aspect of the present invention, even when the writing current increases due to a large number of the writing subject memory cells having the first logic level, and the power source voltage decreases as a result, it is possible to maintain the writing prohibition voltage to be applied to the writing subject memory cells having the second logic level as the high voltage to prevent the writing current from flowing. Accordingly, it is possible to prevent the data with the first logic level from being erroneously written in the memory cells into which the data with the second logic level is to be written.

### BRIEF DESCRIPTION OF THE DRAWINGS

FIG. 1 is a block diagram showing an internal configuration of a non-volatile semiconductor memory according to a first embodiment of the present invention;

FIG. 2 is a sectional view showing a configuration of a memory cell of the non-volatile semiconductor memory according to the first embodiment of the present invention;

FIG. 3 is a circuit diagram showing an example of an internal configuration of a writing control unit disposed in a column driver of the non-volatile semiconductor memory according to the first embodiment of the present invention;

FIGS. 4(a) and 4(b) are time charts showing a writing operation of the writing control unit of the column driver of the non-volatile semiconductor memory according to the first embodiment of the present invention; and

FIG. 5 is a circuit diagram showing an example of an internal configuration of a writing control unit disposed in a column driver of a non-volatile semiconductor memory according to a second embodiment of the present invention.

### DETAILED DESCRIPTION OF PREFERRED EMBODIMENTS

Hereunder, preferred embodiments of the present invention will be explained with reference to the accompanying drawings.

In a non-volatile semiconductor memory of the present invention, it is configured such that a high source voltage is applied to a source region of each of specific ones of writing subject memory cells, to which data having a first logic level is to be written, among memory cells thereof. Further, it is configured such that a low voltage is applied to a drain region of each of the specific ones of the writing subject memory cells, to which the data having the first logic level is to be written, among the memory cells thereof. Accordingly, a writing current flows in each of the specific ones of the writing subject memory cells having the first logic level.

Further, in the non-volatile semiconductor memory of the present invention, it is configured such that the high source voltage is applied to the source region of each of specific ones of the writing subject memory cells, to which data having a second logic level is to be written, among the memory cells. Further, it is configured such that the writing prohibition voltage higher than the power source voltage is applied to the drain region of each of the specific ones of the writing subject memory cells, to which the data having the second logic level is to be written, among the memory cells. As a result, the writing current is prevented from flowing in the specific ones of the writing subject memory cells.

### First Embodiment

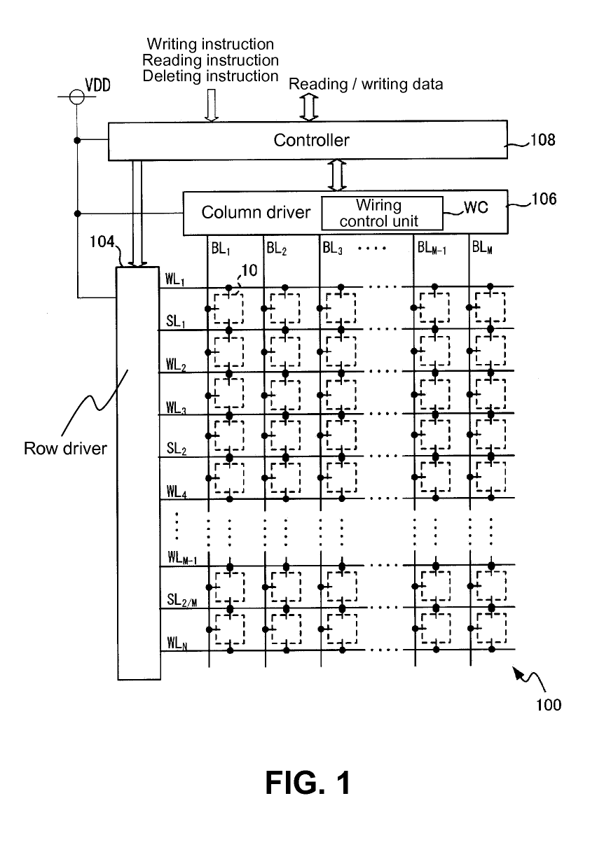

A first embodiment of the present invention will be explained with reference to FIGS. 1 to 4. FIG. 1 is a block diagram showing an internal configuration of the non-volatile semiconductor memory according to the first embodiment of the present invention.

As shown in FIG. 1, the non-volatile semiconductor memory includes a memory cell array 100, a row driver 104, a column driver 106, and a controller 108.

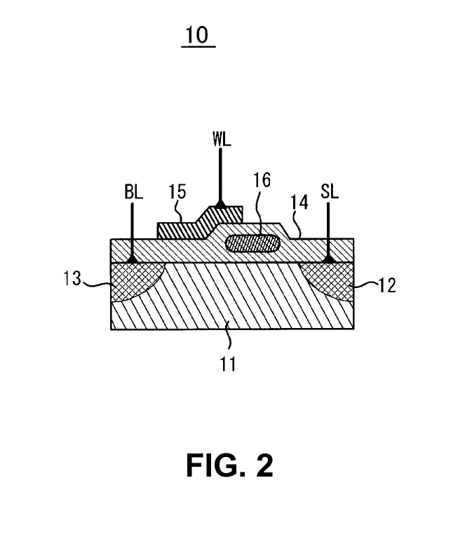

In the embodiment, a plurality of bit lines BL₁ to BLₘ (m is an integer greater than two) is formed in the memory cell array 100. Further, a plurality of word lines WL₁ to WLₙ (n is an integer greater than one) and a plurality of source lines SL₁ to SL_{n/2} are formed in the memory cell array 100, and the word lines WL₁ to WLₙ and the source lines SL₁ to SL_{n/2} are arranged to cross each of the bit lines BL₁ to BLₘ. More specifically, the word lines WL₁ to WLₙ and the source lines SL₁ to SL_{n/2} are arranged alternately such as the word line WL₁, the source line SL₁, the word line WL₁, the source line SL₁, the word line WL₃, the source line SL₃, etc. Further, the memory cell array 100 includes a memory cell 10 of a split gate type as shown in FIG. 2 disposed on each of a crossing point of the bit line BL₁ to BLₘ and the word lines WL₁ to WLₙ or the source lines SL₁ to SL_{n/2}.

FIG. 2 is a sectional view showing a configuration of the memory cell 10 of the non-volatile semiconductor memory according to the first embodiment of the present invention. As shown in FIG. 2, the memory cell 10 is formed of, for example, an n-channel MOSFET (Metal Oxide Semiconductor Field Effect Transistor) of the split gate type. More specifically, the memory cell 10 includes a p-type silicon substrate 11, and an n-type source region 12 and an n-type drain region 13 are formed on the silicon substrate 11. Further, a gate insulation film 14 formed of SiO₂ and a selection gate electrode 15 are disposed to cover the source region 12 and the drain region 13, thereby forming a laminated structure. In the memory cell 10 shown in FIG. 2, a floating gate electrode 15 is disposed in the gate insulation film 14.

In the embodiment, when a reading instruction or a deleting instruction is supplied to the controller 108, the controller 108 is configured to supply address information indicating a reading destination or a deleting destination to the row driver 104. Further, when a writing instruction is supplied to the controller 108, the controller 108 is configured to supply a writing operation signal PROG to the row driver 104 and the column driver 106 for performing a writing operation. Further, the controller 108 is configured to supply address information indicating a writing destination to the row driver 104. Further, the controller 108 is configured to supply writing data DT₁ to DTₘ to the column driver 106, so that each of the writing data DT₁ to DTₘ is written in each of the memory cells 10 in the number of m connected to one word line WL.

In the embodiment, the row driver 104 is provided for selecting the one word line WL among the word lines WL₁ to WLₙ formed in the memory cell array 100 based on the address information described above according to the writing operation signal PROG supplied from the controller 108, so that the row driver 104 supplies a gate voltage to the one word line WL. Accordingly, each of the memory cells 10 connected to the one word line WL, to which the gate voltage is supplied, becomes a reading target, a deleting target, or a writing target of the data. Further, the row driver 104 is configured to generate various voltages corresponding to the reading operation, the deleting operation, or the reading operation of the data, so that the row driver 104 applies the various voltages to the source line SL.

In the embodiment, the column driver 106 is provided for generating various voltages corresponding to the reading operation, the deleting operation, or the reading operation of the data according to the writing operation signal PROG supplied from the controller 108, so that the column driver 106 applies the various voltages to corresponding ones of the bit lines BL₁ to BLₘ.

As described above, in the embodiment, the non-volatile semiconductor memory shown in FIG. 1 includes the memory cells 10 arranged in the matrix pattern and the driver units (the row driver 104, the column driver 106, and the controller 108) for driving the memory cells 10.

The writing operation of the non-volatile semiconductor memory shown in FIG. 1 will be explained next. First, according to the wiring operation signal PROG, the row driver 104 applies a selection voltage to the one word line WL based on the address information described above, so that the one word line WL becomes the writing target. Further, the row driver 104 generates a source voltage V_{PP} having a high voltage level according to a power source voltage VDD supplied, so that the non-volatile semiconductor memory is driven. Then, the row driver 104 applies the source voltage V_{PP} to the source line SL adjacent to the one word line WL according to the writing operation signal PROG. It is noted that the source voltage V_{PP} has the voltage level higher than the power source voltage VDD.

In the embodiment, according to the wiring operation signal PROG, a wiring control unit WC disposed in the column driver 106 is configured to generate a voltage (described later) corresponding to each of the writing data DT₁ to DTₘ supplied from the controller 108, so that the wiring control unit WC applies the voltage to each of the bit lines BL₁ to BLₘ.

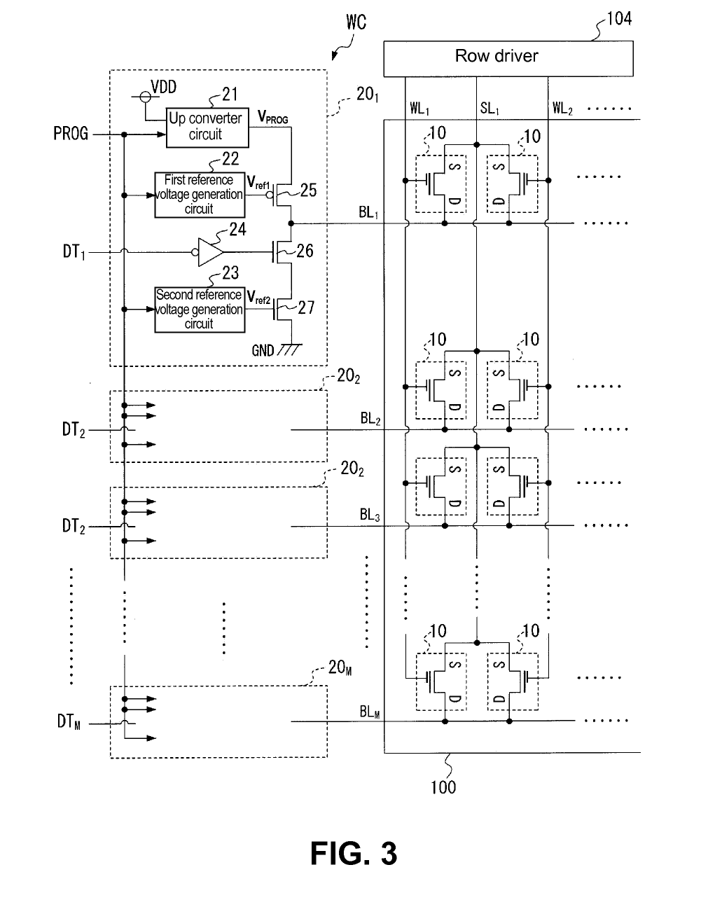

FIG. 3 is a circuit diagram showing an example of an internal configuration of the writing control unit WC disposed in the column driver 106 of the non-volatile semiconductor memory according to the first embodiment of the present invention.

As shown in FIG. 3, the writing control unit WC includes writing voltage generation circuits 20₁ to 20ₘ each disposed to correspond to each of the bit lines BL₁ to BLₘ. The writing voltage generation circuits 20₁ to 20ₘ have an identical internal configuration. Each of the writing voltage generation circuits 20₁ to 20ₘ is formed of an up converter circuit 21; a first reference voltage generation circuit 22; a second reference voltage generation circuit 23; an inverter 24; an FET 25 or a p-channel MOSFET; an FET 26 or an n-channel MOSFET; and an FET 25 or an n-channel MOSFET.

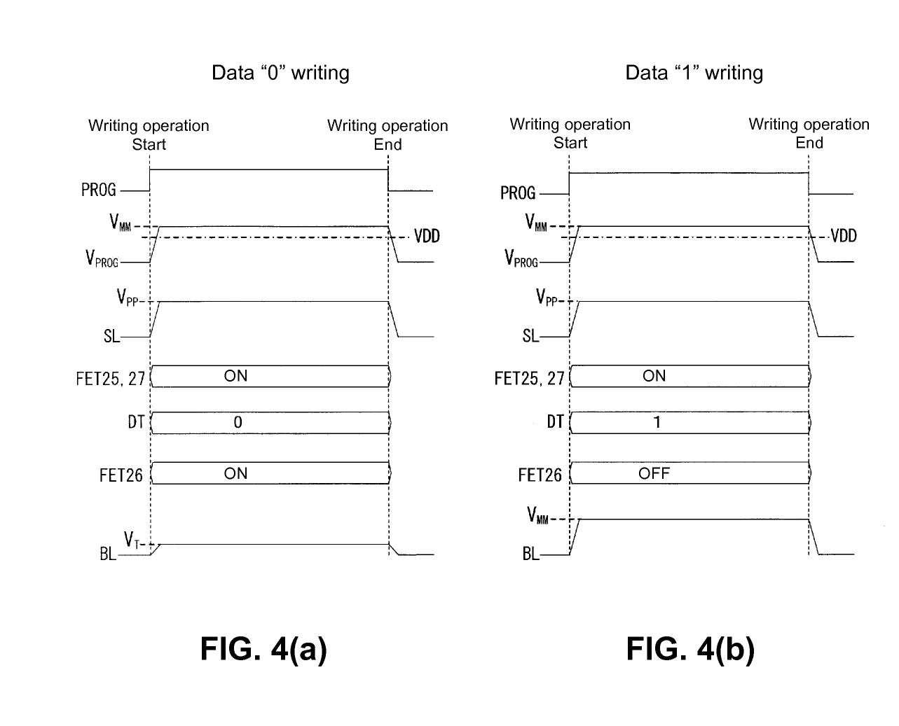

FIGS. 4(a) and 4(b) are time charts showing the writing operation of the writing control unit WC of the column driver 106 of the non-volatile semiconductor memory according to the first embodiment of the present invention.

As shown in FIGS. 4(a) and 4(b), the up converter circuit 21 is provided for increasing the power source voltage VDD over a period of time when the wiring operation signal PROG is in the logic level “1” for prompting the writing operation. More specifically, the up converter circuit 21 is provided for generating a writing prohibition voltage V_{PROG} having a peak voltage V_{MM} at a voltage level higher than the power source voltage VDD, so that the up converter circuit 21 supplies the writing prohibition voltage V_{PROG} to a source terminal of the FET 25.

In the embodiment, the first reference voltage generation circuit 22 is provided for generating a first reference voltage V_{ref1} over the period of time when the wiring operation signal PROG is in the logic level “1” for prompting the writing operation, so that the FET 25 becomes an on state. Accordingly, the up converter circuit 21 supplies the first reference voltage V_{ref1} to a gate terminal of the FET 25. Further, the first reference voltage generation circuit 22 is provided for generating the first reference voltage V_{ref1} over a period of time when the wiring operation signal PROG is in the logic level “0”, so that the FET 25 becomes an off state. Accordingly, the up converter circuit 21 supplies the first reference voltage V_{ref1} to the gate terminal of the FET 25.

In the embodiment, the second reference voltage generation circuit 23 is provided for generating a second reference voltage V_{ref2} over the period of time when the wiring operation signal PROG is in the logic level “1” for prompting the writing operation, so that the FET 27 becomes the on state. Accordingly, the up converter circuit 21 supplies the second reference voltage V_{ref2} to a gate terminal of the FET 27. Further, the second reference voltage generation circuit 23 is provided for generating the second reference voltage V_{ref2} over the period of time when the wiring operation signal PROG is in the logic level “0”, so that the FET 27 becomes the off state. Accordingly, the up converter circuit 21 supplies the second reference voltage V_{ref2} to the gate terminal of the FET 27.

In the embodiment, the inverter 24 is provided for supplying a signal with an inverted logic level of the logic level of the writing data DT supplied from the controller 108 to a gate terminal of the FET 26. When the wiring operation signal PROG is in the logic level “1” for prompting the writing operation, the FET 25 becomes the one state according to the first reference voltage V_{ref1} supplied from the first reference voltage generation circuit 22, so that the FET 25 supplies the writing prohibition voltage V_{PROG} supplied from the up converter circuit 21 to the bit line BL.

In the embodiment, when the wiring operation signal PROG is in the logic level “1” for prompting the writing operation, the FET 27 becomes the one state according to the second reference voltage V_{ref2} supplied from the second reference voltage generation circuit 23, so that the FET 27 supplies a ground voltage GND with a low voltage level applied to a source terminal thereof to a source terminal of the FET 26 through a drain terminal thereof.

In the embodiment, when the writing data DT indicating the logic level “1” is supplied to the FET 26, the FET 26 becomes the off state. On the other hand, when the writing data DT indicating the logic level “0” is supplied to the FET 26, the FET 26 becomes the on state, so that the FET 26 supplies the ground voltage GND supplied from the FET 27 to the bit line BL.

As shown in FIG. 4(a), the writing control unit WC with the configuration shown in FIG. 3 is provided for applying a low voltage V_{T} to the bit line BL, to which specific ones of the memory cells 10 are connected. It is noted that the writing data DT with the logic level “0” is to be written in the specific ones of the writing voltage generation circuit. For example, when the writing data DT₁ has the logic level “0”, the FET 26 of the writing voltage generation circuit 20₁ becomes the on state, so that the ground voltage GND having the low voltage level is supplied to the bit line BL₁ through the FET 26 and the FET 27.

More specifically, during the period of time described above, the writing prohibition voltage V_{PROG} with the high voltage level is applied to the bit line BL₁ through the FET 25. However, the ground voltage GND having the low voltage level is also supplied to the bit line BL₁ through the FET 26 and the FET 27. Accordingly, as shown in FIG. 4(a), the low voltage V_{T} is applied to the bit line BL₁, that is, the drain region 13 of the memory cell 10.

Further, in the embodiment, as shown in FIG. 4(a), the source voltage V_{PP} with the high voltage level supplied from the row driver 104 is applied to the source region 12 of the memory cell 10. In other words, the high voltage (V_{PP}) is applied to the source region 12 of the memory cell 10, and the low voltage (V_{T}) is applied to the drain region 13 of the memory cell 10. As a result, as shown in FIG. 4(a), the writing current flows between the source region 12 and the drain region 13. When the writing current flows, electrons are introduced into the floating gate region of the memory cell 10 connected to the bit line BL₁, so that the memory cell 10 is set in the state that the data with the logic level “0” is written thereto.

On the other hand, as shown in FIG. 4(b), the writing control unit WC is provided for applying the writing prohibition voltage VPROG to the bit line BL, to which specific ones of the memory cells 10 are connected. It is noted that the writing data DT with the logic level “1” is to be written in the specific ones of the writing voltage generation circuit. For example, when the writing data DT2 has the logic level “1”, the FET 26 of the writing voltage generation circuit 20₂ becomes the off state, so that only the writing prohibition voltage V_{PROG} having the peak voltage V_{MM} with the high voltage level is supplied to the bit line BL₂ through the FET 25 as shown in FIG. 4(b). In other word, the writing prohibition voltage V_{PROG} with the high voltage level is supplied to the drain region 13 of the memory cell 10 through the bit line BL₂.

More specifically, during the period of time described above, the source voltage VPP with the high voltage level supplied from the row driver 104 is applied to the source region 12 of the memory cell 10. Accordingly, the high voltages (V_{PROG} and V_{PP}) are applied to the source region 12 and the drain region 13 of the memory cell 10. As a result, the writing current does not flow between the source region 12 and the drain region 13. Therefore, electrons are not introduced into the floating gate region of the memory cell 10 connected to the bit line BL₂, so that the memory cell 10 is set in the state that the data with the logic level “1” is written thereto.

In general, when the data having the logic level “0” is written in the large number of the memory cells 10, the wiring current flowing into each of the memory cells 10 has a large total sum, thereby decreasing the power source voltage VDD. As described above, the writing prohibition voltage V_{PROG} is applied to the drain region 13 of the memory cell 10, to which the data having the logic level “1” is written, for preventing the writing current from flowing thereto. When the power source voltage VDD decreases, the writing prohibition voltage V_{PROG} decreases as well. At this moment, if the writing prohibition voltage V_{PROG} with the high voltage level applied to the drain region 13 becomes below a specific voltage level relative to the source voltage V_{PP} with the high voltage level applied to the source region 12, the writing current may flow into the memory cell 10. If the wiring current flows into the memory cell 10, the data with the logic level “0” is erroneously written to the memory cell 10, to which the data with the logic level “1” is to be written.

To this end, in the embodiment, in the writing control unit WC shown in FIG. 3, the up converter circuit 21 is provided for generating the writing prohibition voltage V_{PROG} through increasing the level of the power source voltage VDD. Accordingly, it is possible to prevent the data from being erroneously written to the memory cell 10.

More specifically, in the embodiment, it is configured to estimate the decrease amount of the power source voltage VDD due to the increase in the writing current, so that the power source voltage VDD is increased by the decrease amount to generate the writing prohibition voltage V_{PROG}. Accordingly, even when the power source voltage VDD decreases, it is possible to maintain the writing prohibition voltage V_{PROG} at the high voltage level for preventing the writing current from flowing into the memory cell 10. Accordingly, it is possible to prevent the data with the logic level “0” from being erroneously written to the memory cell 10 as the writing subject memory, to which the data with the logic level “1” is to be written.

### Second Embodiment

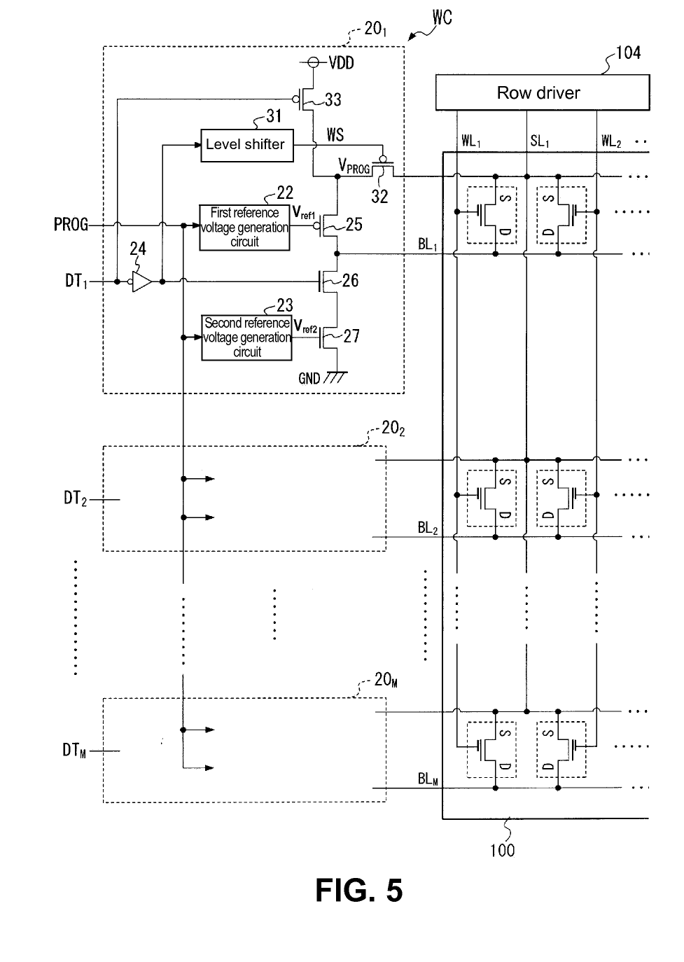

A second embodiment of the present invention will be explained next with reference to FIG. 5. FIG. 5 is a circuit diagram showing an example of an internal configuration of the writing control unit WC disposed in the column driver 106 of the non-volatile semiconductor memory according to the second embodiment of the present invention.

As shown in FIG. 5, each of the writing voltage generation circuits 20₁ to 20ₘ has an internal configuration different from that shown in FIG. 3. More specifically, each of the writing voltage generation circuits 20₁ to 20ₘ does not have the up converter circuit 21. Instead, each of the writing voltage generation circuits 20₁ to 20ₘ has a level shifter 31, an FET 32 or a p-channel MOSFET, and an FET 33 or a p-channel MOSFET.

An operation of the writing voltage generation circuits 20₁ to 20ₘ will be explained while a main focus is first placed on the level shifter 31, the FET 32, and the FET 33.

In the embodiment, the inverter 24 is provided for inverting the logic level of the signal, or the logic level of the writing data DT, and the level shifter 31 is provided for shifting the level of the signal so that the signal is capable of driving the FET 32. Further, the level shifter 31 is provided for supplying an inverted writing data signal WS with the shifted level to a gate terminal of the FET 32. A source terminal of the FET 32 is connected to the source line SL, and a drain terminal of the FET 32 is connected to the source terminal of the FET 25.

In the embodiment, when the inverted writing data signal WS is the signal corresponding to the logic level “1”, the FET 32 becomes the off state. On the other hand, when the inverted writing data signal WS is the signal corresponding to the logic level “0”, the FET 32 becomes the on state, so that the voltage on the source line SL is supplied to the source terminal of the FET 25 as the writing prohibition voltage VPROG.

In the embodiment, when the writing data DT has the logic level “1”, the FET 33 becomes the off state. On the other hand, when the writing data DT has the logic level “0”, the FET 33 becomes the on state, so that the power source voltage VDD is supplied to the source terminal of the FET 25.

An operation of the writing voltage generation circuits 201 to 20m shown in FIG. 5 will be explained next.

First, the controller 108 supplies the writing operation signal PROG with the logic level “1” for prompting the writing operation, and the wiring data DT with the logic level “0” is supplied, the FET 25, the FET 26, the FET 27, and the FET 33 of the writing voltage generation circuit 20 become the on state, and the FET 32 thereof becomes the off state. As a result, the power source voltage VDD is applied to the bit line BL through the FET 33 and the FET 25, and the ground voltage GND is applied to the bit line BL through the FET 27 and the FET 26. Accordingly, as shown in FIG. 4(a), the low voltage V_{T} is applied to the bit line BL, that is, the drain region 13 of the memory cell 10.

Further, in the embodiment, as shown in FIG. 4(a), the source voltage V_{PP} with the high voltage level supplied from the row driver 104 is applied to the source region 12 of the memory cell 10 through the source line SL. In other words, the high voltage (V_{PP}) is applied to the source region 12 of the memory cell 10, and the low voltage (V_{T}) is applied to the drain region 13 of the memory cell 10. As a result, as shown in FIG. 4(a), the writing current flows between the source region 12 and the drain region 13. When the writing current flows, electrons are introduced into the floating gate region of the memory cell 10 connected to the bit line BL, so that the memory cell 10 is set in the state that the data with the logic level “0” is written thereto.

On the other hand, when the wiring data DT with the logic level “1” is supplied, the FET 25, the FET 27 and the FET 32 of the writing voltage generation circuit 20 become the on state, and the FET 26 and the FET 33 thereof become the off state. As a result, the FET 32 converts the source voltage V_{PP} applied to the source line SL to the writing prohibition voltage VPROG, and the writing prohibition voltage V_{PROG} is applied to the bit line BL through the FET 25.

Accordingly, the source voltage V_{PP} is applied to the source region 12 of the memory cell 10. Further, the writing prohibition voltage V_{PROG} having the voltage value the same as the high voltage (V_{PP}) is applied to the drain region 13 of the memory cell 10. As a result, as shown in FIG. 4(a), the writing current does not flow between the source region 12 and the drain region 13. When the writing current does not flow, the memory cell 10 is set in the state that the data with the logic level “1” is written thereto.

As described above, in the writing voltage generation circuit 20 shown in FIG. 5, the FET 32 supplies and relays the source voltage V_{PP} applied to the source region 12 of the memory cell 10 as the writing prohibition voltage V_{PROG} to the drain region 13 of the memory cell 10, to which the writing data DT with the logic level “1” is to be written, so that the writing current does not flow into the memory cell 10. Accordingly, even when the power source voltage VDD decreases, the writing current does not flow between the source region 12 and the drain region 13 of the memory cell 10. Accordingly, it is possible to prevent the data with the logic level “0” from being erroneously written to the memory cell 10 as the writing subject memory, to which the data with the logic level “1” is to be written.

As described above, in the embodiment, the writing voltage generation circuit 20 has the internal configuration shown in FIG. 5. Accordingly, it is not necessary to provide the up converter circuit 21. As a result, it is possible to reduce the size of the circuit as opposed to the internal configuration shown in FIG. 3.

The disclosure of Japanese Patent Application No. 2011-020988, filed on Feb. 2, 2011, is incorporated in the application by reference.

While the invention has been explained with reference to the specific embodiments of the invention, the explanation is illustrative and the invention is limited only by the appended claims.

What is claimed is:

1. A non-volatile semiconductor memory, comprising:
a plurality of memory cells each having an MOSFET (Metal Oxide Semiconductor Field Effect Transistor) structure; and
a driver for selectively driving the memory cells,
wherein said driver includes a first drive portion and a second drive portion,
said first drive portion is configured to apply a source voltage higher than a power source voltage to a source region of each of writing subject memory cells among the memory cells based on the power source voltage according to a wiring instruction for wiring first data or second data to the writing subject memory cells,
said second drive portion is configured to apply a specific low voltage to a drain region of each of a first group of the writing subject memory cells, to which the first data having a first logic level is to be written according to the wiring instruction, so that a writing current flows in the first group of the writing subject memory cells, and
said second drive portion is configured to apply a specific high voltage higher than the power source voltage as a writing prohibition voltage to a drain region of each of a second group of the writing subject memory cells, to which the second data having a second logic level different from the first logic level is to be written according to the wiring instruction, so that the writing current is prevented from flowing in the second group of the writing subject memory cells.

2. The non-volatile semiconductor memory according to claim 1, wherein said second drive portion includes,
an up converter circuit for increasing the power source voltage to generate the writing prohibition voltage;
a first transistor for applying the writing prohibition voltage to the drain region of each of the second group of the writing subject memory cells according to the wiring instruction; and
a second transistor configured to become an on state for applying a ground voltage to the drain region of each of the second group of the writing subject memory cells according to the wiring instruction when the first data having the first logic level is supplied according to the wiring instruction,
wherein said second transistor is configured to become an off state when the second data having the second logic level is supplied.

3. The non-volatile semiconductor memory according to claim 1, wherein said second drive portion includes a switching portion for converting the source voltage to the writing prohibition voltage, and for relaying and supplying the writing prohibition voltage to the drain region of each of the second group of the writing subject memory cells.

4. The non-volatile semiconductor memory according to claim 3, wherein said switching portion includes,
a first transistor configured to become an on state when the second data having the second logic level is supplied so that the first transistor retrieves the source voltage as the writing prohibition voltage; and
a second transistor for applying the writing prohibition voltage retrieved with the first transistor to the drain region of each of the second group of the writing subject memory cells according to the wiring instruction.

5. The non-volatile semiconductor memory according to claim 4, wherein said second drive portion further includes a third transistor configured to become an on state when the first data having the first logic level is supplied so that the third transistor applies the ground voltage to the drain region of each of the second group of the writing subject memory cells according to the wiring instruction,
wherein said third transistor is configured to become an off state when the second data having the second logic level is supplied.

6. The non-volatile semiconductor memory according to claim 1, wherein each of said memory cells has the MOSFET structure of a split gate type.
